(19) United States
(12) Patent Application Publication
(10) Pub. No.: US 2012/0256273 A1
(43) Pub. Date: Oct. 11, 2012

(54) METHOD OF UNIFYING DEVICE PERFORMANCE WITHIN DIE

(76) Inventors: Yu-Ho Chiang, Taichung City (TW); Ming-Tsung Chen, Hsin-Chu Hsien (TW); Wai-Yi Lien, Hsinchu City (TW); Chih-Kai Hsu, Tainan City (TW); Chun-Liang Hou, Hsinchu County (TW)

(21) Appl. No.: 13/228,455

(22) Filed: Sep. 9, 2011

Related U.S. Application Data
(60) Provisional application No. 61/473,176, filed on Apr. 8, 2011.

(51) Int. Cl. H01L 29/06; H01L 21/765; H01L 21/762

(52) U.S. Cl. 257/401; 438/424; 438/454; 257/E29.007; 257/E21.545; 257/E21.574

(57) ABSTRACT

A method of unifying device performance within an integrated circuit die includes providing a layout of an integrated circuit die with multiple functional circuit blocks; filling a field between the multiple functional circuit blocks with dummy diffusion patterns; and filling the field between the multiple functional circuit blocks with dummy gate patterns such that the dummy gate patterns and the dummy diffusion patterns are completely overlapped.

### CROSS REFERENCE TO RELATED APPLICATIONS

This application claims the benefit of U.S. provisional application Ser. No. 61/473,176 filed Apr. 8, 2011, which is hereby incorporated by reference.

### BACKGROUND OF THE INVENTION

1. Field of the Invention

The present invention relates generally to the filed of semiconductor fabrication. More particularly, the present invention relates to a method of unifying device performance, specifically in terms of ON current (I_{ON}) range between MOS transistors, within an integrated circuit die.

2. Description of the Prior Art

As known in the art, in semiconductor wafer fabrication, a rapid thermal anneal (RTA) process is often used to activate dopants, diffuse dopants, re-crystallize structures, etc. RTA processes are typically performed by utilizing halogen lamp-based heating equipment or lasers which direct radiation onto a wafer surface in order to change the wafer temperature.

During performance of these RTA processes, temperature variations occur at different points or areas within the integrated circuit die. Temperature variations within a die are due primarily to differences in thermal absorption and emission caused by different film stacks at different locations. As device dimensions shrink, the impact of these temperature variations has an increased effect on device performance by affecting electrical response or behavior at different locations within a die. Variations in device performance within a die have been observed and are attributed to temperature non-uniformity when the wafer (and its dies) undergoes front-side annealing schemes. These temperature variations not only result from differences in film stack materials, but also result from the pattern density across the die.

In semiconductor processing, dummy fill patterns have been used in diffusion mask and/or gate mask to prevent dishing effects from chemical-mechanical polishing (CMP) and to minimize the effects of device-to-device variations in pattern density. For example, in conventional shallow trench isolation processes, diffusion islands are isolated by oxide filled trenches. The formation of the shallow trench involves etching of the silicon trench patterns into a silicon substrate and subsequently filling the trenches with a thick oxide layer. The oxide layer is then planarized by using processes such as CMP, resist etchback, or oxide etchback processes. In these cases, the polish rate or etch rate is a function of the pattern density, which is defined as the percentage of the area that is occupied by diffusion patterns.

In order to ensure a uniform removal of the oxide over an entire wafer or substrate, the pattern density should ideally remain relatively the same over all areas. To achieve the relatively uniform pattern density, the field on the semiconductor substrate is often filled with dummy diffusion patterns. After filling with the dummy fill patterns, circuit areas and the field areas on the semiconductor substrate will have relatively similar pattern densities. However, the conventional dummy fill patterns deteriorate the variations in device performance within a die.

A semiconductor chip is typically formed by integrating up to millions or billions of transistors onto a single chip of semiconductor material. The uniformity of these transistors is generally of critical importance in the manufacturing of IC circuits. There is still a need for an improved fabrication process or method that is capable of unifying device performance and/or reducing temperature variations within an integrated circuit die.

### SUMMARY OF THE INVENTION

It is one objective of the present invention to provide an improved method of unifying device performance, specifically in terms of ON current (I_{ON}) range between MOS transistors, within an integrated circuit die, in order to solve the above-mentioned prior art problems and shortcomings.

According to one embodiment of this invention, a method of unifying device performance within an integrated circuit die includes providing a layout of an integrated circuit die with multiple functional circuit blocks; filling a field between the multiple functional circuit blocks with dummy diffusion patterns; and filling the field between the multiple functional circuit blocks with dummy gate patterns such that the dummy gate patterns and the dummy diffusion patterns are completely overlapped.

According to another embodiment of this invention, a method of unifying device performance within an integrated circuit die includes providing a layout of an integrated circuit die with multiple functional circuit blocks; filling a field between the multiple functional circuit blocks with dummy diffusion patterns; and filling the field between the multiple functional circuit blocks with strip-shaped, dummy gate patterns such that the strip-shaped, dummy gate patterns and the dummy diffusion patterns are partially overlapped and that two ends of each of the strip-shaped, dummy gate patterns protrude out of a longer side of the active area by a distance S that is less than a width W of the dummy diffusion pattern.

According to another embodiment of this invention, a method of unifying device performance within an integrated circuit die includes providing a layout of an integrated circuit die with multiple functional circuit blocks; filling a field between the multiple functional circuit blocks with dummy diffusion patterns; and filling the field between the multiple functional circuit blocks with dummy gate patterns such that a reflectivity of the integrated circuit die is in a range of about 0.25-0.4.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a top view of an integrated circuit die schematically showing the large ON current (I_{ON}) range;

FIG. 2 is a schematic, cross-sectional diagram showing different types of the dummy fill patterns according to the embodiments of this invention;

FIGS. 3-4 are schematic diagrams showing a method for fabricating a semiconductor device such as MOS transistor devices on a substrate according to one embodiment of this invention;

FIG. 5 is a flow diagram of a method of unifying device performance within an integrated circuit die according to the invention;

FIGS. 6-7 are schematic diagrams showing a method for fabricating a semiconductor device such as MOS transistor devices on a substrate according to another embodiment of this invention;

FIG. 7A is a schematic diagram of a portion of an integrated circuit die after filling the dummy gate patterns in accordance with another embodiment of this invention; and

FIG. 8 is a flow diagram of a method of unifying device performance within an integrated circuit die according to another embodiment of the invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description, reference is made to the accompanying drawings, which form a part hereof, and in which is shown by way of illustration specific examples in which the embodiments may be practiced. These embodiments are described in sufficient detail to enable those skilled in the art to practice them, and it is to be understood that other embodiments may be utilized and that structural, logical and electrical changes may be made without departing from the described embodiments. The following detailed description is, therefore, not to be taken in a limiting sense, and the included embodiments are defined by the appended claims.

FIG. 1 is a schematic top view of an integrated circuit die 10. The integrated circuit die 10 may comprises a plurality of functional circuit blocks 1-7 including but not limited to, for example, core circuits, peripheral circuits, logic circuits, analog circuits, memory circuits, etc. An open field 8 is provided between the functional circuit blocks 1-7. As previously described, dummy fill structures or patterns may be provided within the open field 8 in diffusion mask and/or gate mask to prevent dishing effects from CMP and to minimize the effects of device-to-device variations in pattern density. However, these conventional dummy fill patterns deteriorate the variations in device performance, specifically in terms of ON current (I_{ON}) range, within the integrated circuit die 10. Hereinafter, the term “ON current (I_{ON}) range”, or “I_{ON} range” in short, refers to the maximum difference in the ON currents of the transistors across the die.

Stilling referring to FIG. 1, the applicants have experimentally found that after treated by RTA or RTP, a large ON current (I_{ON}) range occurs between the transistors disposed at different points or locations of the integrated circuit die 10, for example, between points indicated by arrows 11 and 31 in the respective functional circuit blocks 1 and 3. According to the experimental results, by way of example, the ON current of an NMOSFET may be somewhere between 891.4-911.4 μA/μm at the point indicated by arrow 11, while the ON current of an NMOSFET may be somewhere between 606.3.4-639.0 μA/μm at the point indicated by arrow 31. The large I_{ON} range within a die has adversely and significantly affected the device performance as device dimensions shrink. The present invention addresses this issue.

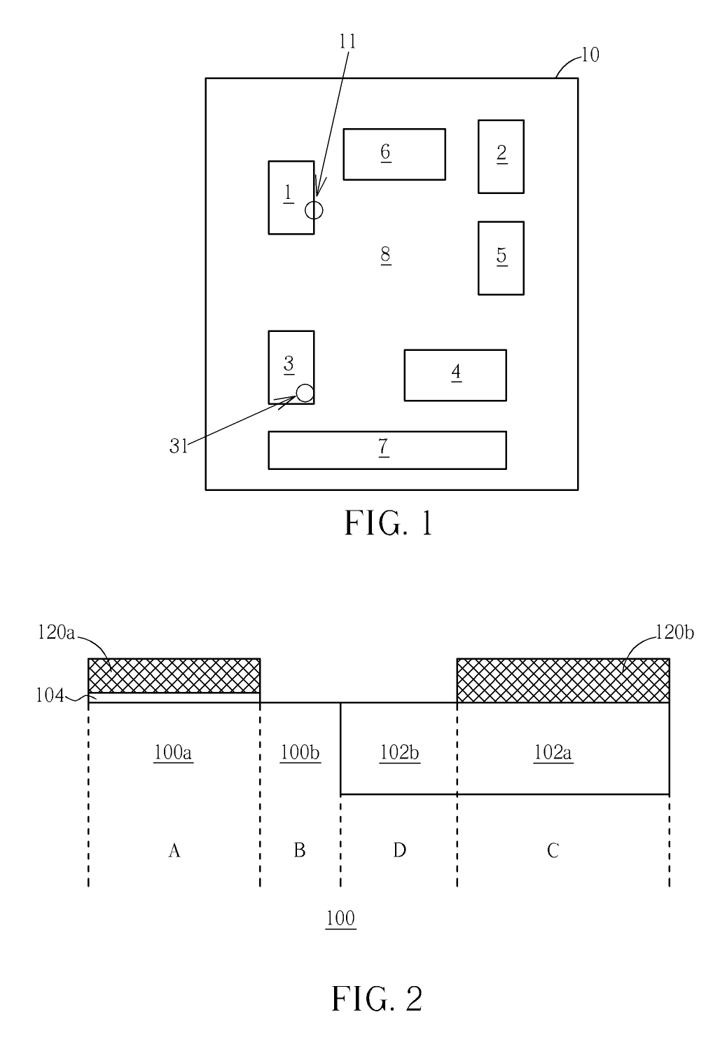

FIG. 2 is a schematic, cross-sectional diagram showing different types of the dummy fill patterns according to the embodiments of this invention. As shown in FIG. 2, in order to access and analyze the impact of the dummy fill patterns on device performance, specifically the I_{ON} range, within a die, the applicants have sorted out four general types of dummy fill patterns. The four types of dummy fill patterns (Types A-D) are formed on or in the semiconductor substrate 100. The dummy fill pattern Type A is defined as a first gate layer 120a such as polysilicon masking a first diffusion dummy pattern 100a with an insulating layer 104 interposed therebetween. The dummy fill pattern Type B is defined as a second diffusion dummy pattern 100b not masked by any gate layer. The dummy fill pattern Type C is defined as a second gate layer 120b masking a first STI pattern 102a. The dummy fill pattern Type D is defined as a second STI pattern 102b not masked by any gate layer. For the sake of simplicity, the aforesaid four types of dummy fill patterns (Types A-D) may be summarized as follows.

Type A (or Mask A): Dummy fill structure with poly dummy gate pattern directly on Si dummy diffusion pattern.

Type B (or Mask B): Dummy fill structure without poly dummy gate pattern directly on Si dummy diffusion pattern.

Type C (or Mask C): Dummy fill structure with poly gate pattern directly on STI.

Type D (or Mask D): Dummy fill structure without poly dummy gate pattern directly on STI.

According to the experiment results, the applicants have found that the dummy fill pattern Type C (or Mask C) is responsible for the large I_{ON} range within a die. That is, the higher percentage the dummy fill pattern Type C occupies within a die, the larger the I_{ON} range is. Reflectivity test of each of the aforesaid four types of dummy fill patterns is also performed. The reflectivity test is performed within an RTA or RTP chamber with ellisometer lamp (wavelength: 810 nm) as heating source. Test structure wafers each having respective dummy fill pattern types are treated with standard RTA process. According to the experimental results, Type A (or Mask A) has a reflectivity of about 0.35, Type B (or Mask B) has a reflectivity of about 0.31, Type C (or Mask C) has a reflectivity of about 0.61, and Type D (or Mask D) has a reflectivity of about 0.29. Compared to Types A, B and D (average 0.32), Type C has abnormal higher reflectivity (0.61).

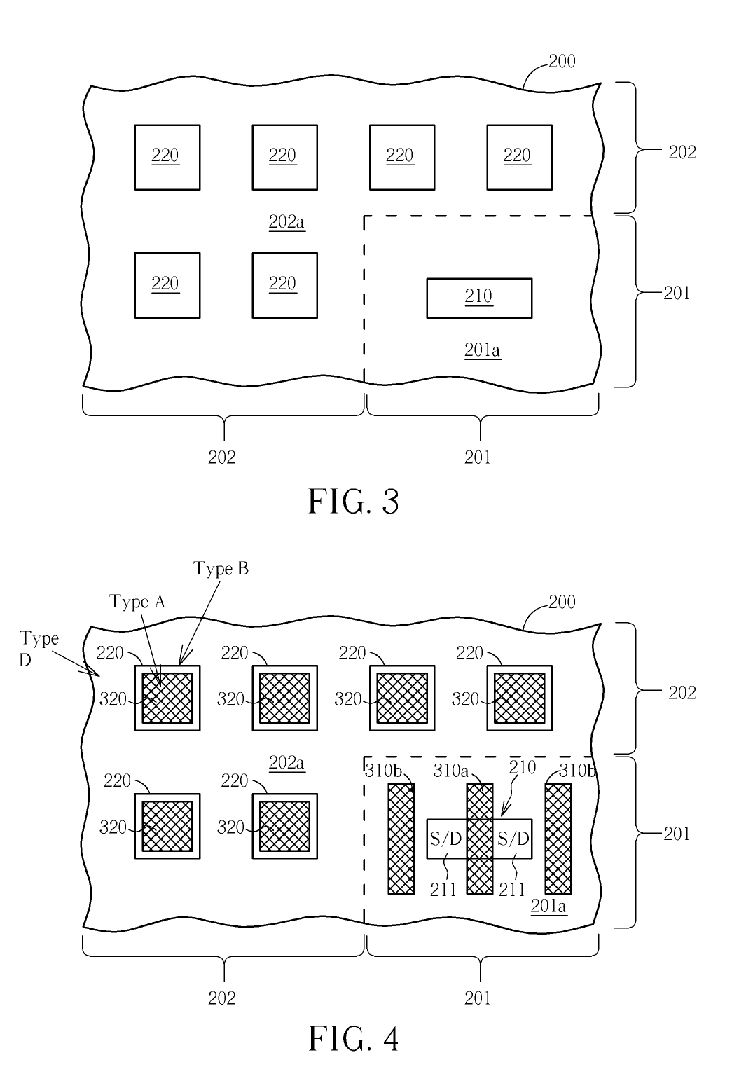

FIGS. 3-4 are schematic diagrams showing an exemplary method for fabricating a semiconductor device such as MOS transistor devices on a substrate according to one embodiment of this invention. As shown in FIG. 3, an integrated circuit die 200 is provided having thereon at least one functional circuit block 201 and an open field 202 that is adjacent to the functional circuit block 201. At least one active area 210 is provided within the functional circuit block 201. The active area 210 may be isolated by an STI region 201a. A plurality of dummy diffusion patterns 220 are provided within the open field 202. Each of the dummy diffusion patterns 220 is isolated from the others by an STI region 202a. The formation of the active area 210 and the plurality of dummy diffusion patterns 220 may include but not limited to the steps: etching the silicon substrate to form STI trenches, depositing trench filling material into the STI trenches, and planarizing the trench filling material. As previously mentioned, these dummy diffusion patterns 220 may avoid dishing effect during the CMP process. Subsequently, a thermal oxidation process may be performed to form gate oxide layer (not shown) on the active area 210 and the dummy diffusion patterns 220.

As shown in FIG. 4, after the formation of the gate oxide layer, at least a gate pattern 310a such as polysilicon gate pattern is formed within the functional circuit block 201. The gate pattern 310a is disposed on the active area 210 and may extend onto the STI region that surrounds the active area 210. A source/drain (S/D) region 211 is formed at either side of the gate pattern 310a. A channel region (not explicitly shown) is defined between the S/D regions 211 underneath the gate pattern 310a. Optionally, optical proximity correction (OPC) patterns or assistant features 310b may be added adjacent to the gate pattern 310a in order to control the critical dimensions (CDs). Within the open field 202, a plurality of dummy gate patterns 320 are disposed on the dummy diffusion patterns 220. It is noteworthy that each of the dummy gate patterns 320 does not extend to the STI region 202a. That is, according to this embodiment, each of the dummy gate patterns 320 and each of the dummy diffusion patterns 220 are completely overlapped, and each of the dummy gate patterns 320 has a surface area that is smaller than or equal to that of each of the dummy diffusion patterns 220. Therefore, there is substantially no dummy fill pattern Type C in the open field 202. By eliminating the dummy fill pattern Type C from the open field 202, the RTA uniformity can be significantly improved. According to this embodiment, preferably, the reflectivity of the integrated circuit die 200 is in a range of about 0.25-0.4.

The S/D regions 211 may be formed by performing a conventional ion implantation process. During the ion implantation process, dopants such as N type or P type dopants may be doped into the active area 210 that is not masked by the gate pattern 310a. A rapid thermal anneal (RTA) process is then carried out to activate dopants in the S/D regions 211. The RTA process may be performed by using a heating source including, but not limited to, tungsten-halogen lamps having a wavelength of about 0.3-4.0 μm, arc-halogen lamps having a wavelength of about 0.1-1.4 μm, lasers such as carbon dioxide laser having a wavelength of about 10.6 μm, argon laser having a wavelength of about 514 nm, or YAG (yttrium aluminum garnet) laser having a wavelength of about 1064 nm.

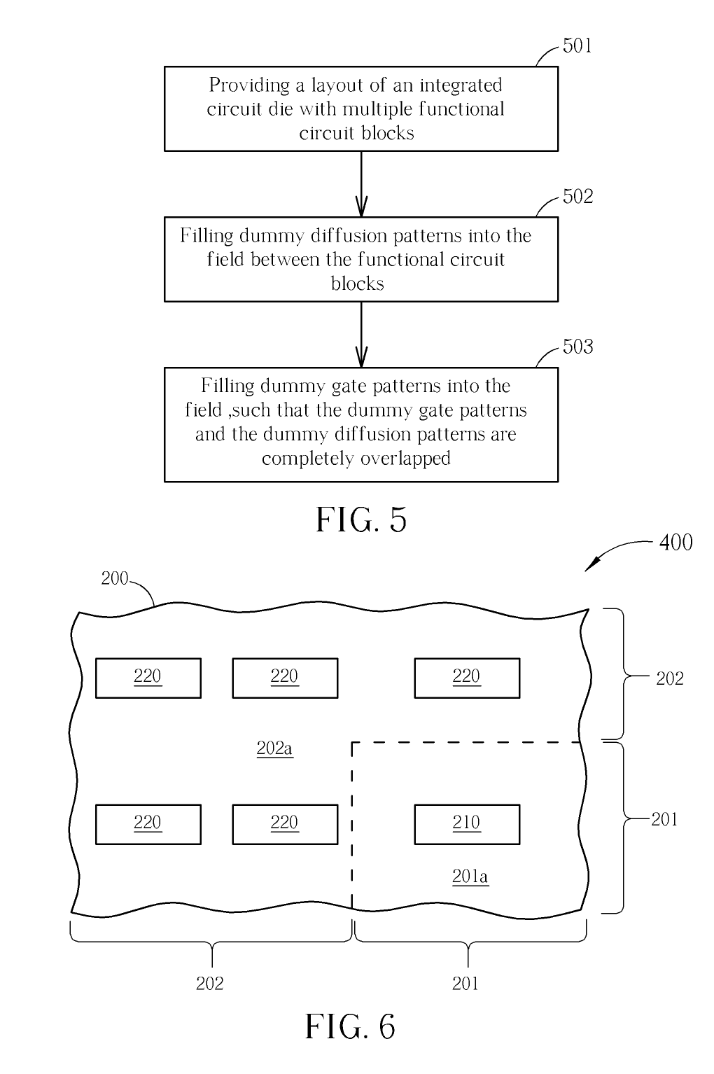

FIG. 5 is a flow diagram of a method of unifying device performance within an integrated circuit die according to the invention. As shown in FIG. 5, in Step 501, a layout of an integrated circuit die with multiple functional circuit blocks is provided. In Step 502, the field between the multiple functional circuit blocks is filled with dummy diffusion patterns. In Step 503, the field between the multiple functional circuit blocks is filled with dummy gate patterns such that the dummy gate patterns and the dummy diffusion patterns are completely overlapped.

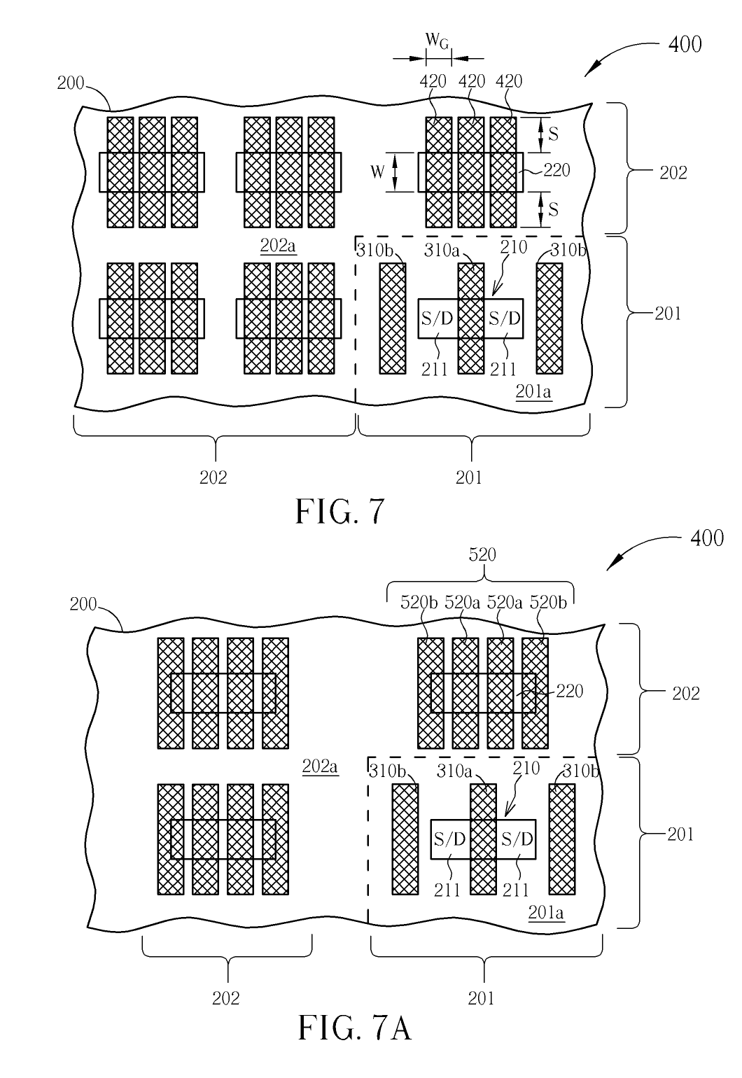

FIGS. 6-7 are schematic diagrams showing a method for fabricating a semiconductor device such as MOS transistor devices on a substrate according to another embodiment of this invention, wherein like numeral numbers designate like elements, regions, or layers. As shown in FIG. 6, likewise, an integrated circuit die 200 is provided having thereon at least one functional circuit block 201 and an open field 202 that is adjacent to the functional circuit block 201. At least one active area 210 is provided within the functional circuit block 201. The active area 210 may be isolated by an STI region 201a. A plurality of dummy diffusion patterns 220 are provided within the non-active, open field 202. Each of the dummy diffusion patterns 220 is isolated from the others by an STI region 202a. The formation of the active area 210 and the plurality of dummy diffusion patterns 220 may include but not limited to the steps: etching the silicon substrate to form STI trenches, depositing trench filling material into the STI trenches, and planarizing the trench filling material. As previously, these dummy diffusion patterns 220 may avoid dishing effect during the CMP process. Subsequently, a thermal oxidation process may be performed to form gate oxide layer (not shown) on the active area 210 and the dummy diffusion patterns 220.

As shown in FIG. 7, after the formation of the gate oxide layer, at least a gate pattern 310a such as polysilicon gate pattern is formed within the functional circuit block 201. The gate pattern 310a is disposed on the active area 210 and may extend onto the STI region that surrounds the active area 210. A source/drain (S/D) region 211 is formed at either side of the gate pattern 310a. A channel region (not explicitly shown) is defined between the S/D regions 211 underneath the gate pattern 310a. Optionally, optical proximity correction (OPC) patterns or assistant features 310b may be added adjacent to the gate pattern 310a in order to control the critical dimensions (CDs). Within the open field 202, a plurality of strip-shaped, dummy gate patterns 420 are disposed on the dummy diffusion patterns 220. The strip-shaped, dummy gate patterns 420 and the dummy diffusion patterns 220 are partially overlapped. For example, each of the strip-shaped, dummy gate patterns 420 has two ends that are directly disposed on the STI region 202a. The two ends of each of the strip-shaped, dummy gate patterns 420 protrude out of the longer side of the rectangular active area by a distance S, wherein, according to this embodiment, the distance S is less than a width W of the dummy diffusion pattern 220. Preferably, the distance S is smaller than ⅔ W, and is greater than ⅓ W. Further, each of the strip-shaped, dummy gate patterns 420 has a gate width W_{G}, wherein S is greater than W_{G}.

FIG. 7A is a schematic diagram of a portion of an integrated circuit die after filling the dummy gate patterns in accordance with another embodiment of this invention, wherein like numeral numbers designate like elements, regions, or layers. As shown in FIG. 7A, a plurality of strip-shaped, dummy gate patterns 520 are disposed on the dummy diffusion patterns 220. The strip-shaped, dummy gate patterns 520a and the dummy diffusion patterns 220 are partially overlapped. For example, each of the strip-shaped, dummy gate patterns 520a has two ends that are directly disposed on the STI region 202a. The two ends of each of the strip-shaped, dummy gate patterns 520a protrude out of the longer side of the rectangular active area by a distance S, wherein, according to this embodiment, the distance S is less than a width W of the dummy diffusion pattern 220. Preferably, the distance S is smaller than ⅔ W, and is greater than ⅓ W. The strip-shaped, dummy gate patterns 520b and the dummy diffusion patterns 220 are partially overlapped. More specifically, a longer side of the strip-shaped, dummy gate patterns 520b and the dummy diffusion patterns 220 may be partially overlapped.

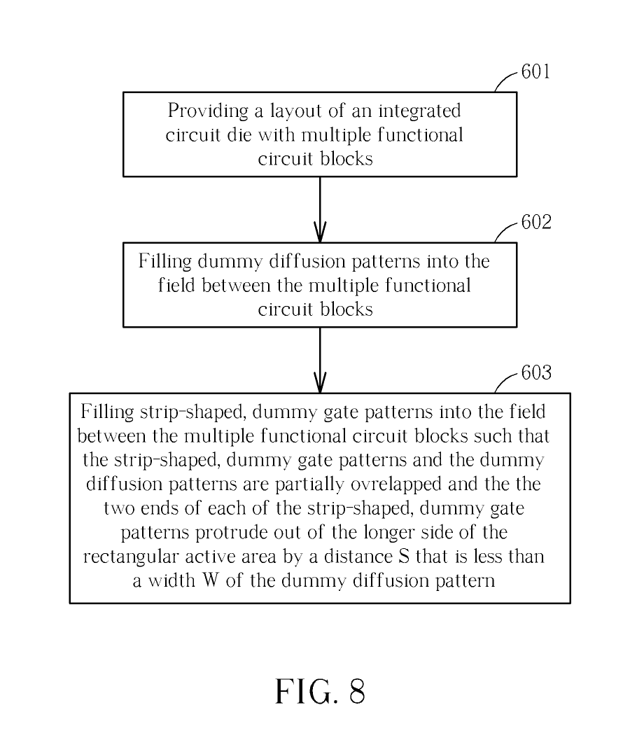

FIG. 8 is a flow diagram of a method of unifying device performance within an integrated circuit die according to another embodiment of the invention. As shown in FIG. 8, in Step 601, a layout of an integrated circuit die with multiple functional circuit blocks is provided. In Step 602, the field between the multiple functional circuit blocks is filled with dummy diffusion patterns. In Step 603, the field between the multiple functional circuit blocks is filled with strip-shaped, dummy gate patterns such that the strip-shaped, dummy gate patterns and the dummy diffusion patterns are partially overlapped and that the two ends of each of the strip-shaped, dummy gate patterns protrude out of the longer side of the rectangular active area by a distance S that is less than a width W of the dummy diffusion pattern.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of unifying device performance within an integrated circuit die, comprising:
providing a layout of an integrated circuit die with multiple functional circuit blocks;
filling a field between the multiple functional circuit blocks with dummy diffusion patterns; and
filling the field between the multiple functional circuit blocks with dummy gate patterns such that the dummy gate patterns and the dummy diffusion patterns are completely overlapped, wherein each of the dummy gate patterns has a surface area that is smaller than or equal to that of each of the dummy diffusion patterns.

2. The method of unifying device performance within an integrated circuit die according to claim 1 wherein the dummy diffusion patterns are silicon dummy diffusion patterns.

3. The method of unifying device performance within an integrated circuit die according to claim 1 wherein the dummy gate patterns are polysilicon dummy gate patterns.

4. The method of unifying device performance within an integrated circuit die according to claim 1 wherein the dummy diffusion patterns are isolated from each other by a shallow trench isolation (STI) region.

5. The method of unifying device performance within an integrated circuit die according to claim 4 wherein the dummy gate patterns and the STI region are not overlapped.

6. A method of unifying device performance within an integrated circuit die, comprising:
providing a layout of an integrated circuit die with multiple functional circuit blocks;
filling a field between the multiple functional circuit blocks with dummy diffusion patterns; and
filling the field between the multiple functional circuit blocks with strip-shaped, dummy gate patterns such that the strip-shaped, dummy gate patterns and the dummy diffusion patterns are partially overlapped and that two ends of each of the strip-shaped, dummy gate patterns protrude out of a longer side of the active area by a distance S that is less than a width W of the dummy diffusion pattern.

7. The method of unifying device performance within an integrated circuit die according to claim 6 wherein the dummy diffusion patterns are silicon dummy diffusion patterns.

8. The method of unifying device performance within an integrated circuit die according to claim 6 wherein the dummy gate patterns are polysilicon dummy gate patterns.

9. The method of unifying device performance within an integrated circuit die according to claim 6 wherein the dummy diffusion patterns are isolated from each other by a shallow trench isolation (STI) region.

10. The method of unifying device performance within an integrated circuit die according to claim 6 wherein the distance S ranges between ⅓ W-⅔ W.

11. The method of unifying device performance within an integrated circuit die according to claim 6 wherein each of the strip-shaped, dummy gate patterns has a gate width W_{G}, wherein S is greater than W_{G}.

12. A method of unifying device performance within an integrated circuit die, comprising:
providing a layout of an integrated circuit die with multiple functional circuit blocks;
filling a field between the multiple functional circuit blocks with dummy diffusion patterns; and
filling the field between the multiple functional circuit blocks with dummy gate patterns such that a reflectivity of the integrated circuit die is in a range of about 0.25-0.4.

13. A layout of an integrated circuit die, comprising:
multiple functional circuit blocks;
a field between the multiple functional circuit blocks;
at least one dummy diffusion pattern within the filed; and
at least one dummy gate pattern within the filed, wherein the dummy gate pattern and the dummy diffusion pattern are completely overlapped, wherein the dummy gate pattern has a surface area that is smaller than or equal to that of the dummy diffusion pattern.
